(19) United States
(12) Patent Application Publication
(10) Pub. No.: US 2020/0291523 A1
(43) Pub. Date: Sep. 17, 2020

(54) CONTINUOUS CHEMICAL VAPOR DEPOSITION (CVD) MULTI-ZONE PROCESS KIT

(71) Applicant: APPLIED MATERIALS, INC., Santa Clara, CA (US)

(72) Inventors: David M. ISHIKAWA, Mountain View, CA (US); Brian H. BURROWS, San Jose, CA (US)

(21) Appl. No.: 16/306,181

(22) PCT Filed: Jun. 2, 2017
(86) PCT No.: PCT/US2017/035712

§ 371 Date: Nov. 30, 2018

Related U.S. Application Data
(60) Provisional application No. 62/344,968, filed on Jun. 2, 2016.

(51) Int. Cl. C23C 16/46; C23C 16/44; C23C 16/455; C23C 16/54

(52) U.S. Cl. CPC C23C 16/46; C23C 16/4412; C23C 16/45502; C23C 16/54; C23C 16/4408; C23C 16/45572

(57) ABSTRACT

Multi-zone process kits for use in a deposition chamber are provided herein. In some embodiments, a multi-zone process kit includes a body having a plurality of deposition zones formed in the body; one or more gas injection conduits fluidly coupled to a first side of each of the plurality of deposition zones via a plurality of gas inlets; an exhaust conduit fluidly coupled to a second side of each of the plurality of deposition zones via a plurality of exhaust apertures; and a multi-zone heater having a plurality of heating zones, wherein one or more of the plurality of heating zones corresponds to each of the plurality of deposition zones.

### FIELD

Embodiments of the present disclosure generally relate to a deposition chamber, and more specifically, to a multi-zone process kit for use in deposition chamber.

### BACKGROUND

Continuous chemical vapor deposition (CVD) is presently used to create a composite coated fiber tow by depositing a coating onto a fiber tow substrate. Typically, separate chambers/furnaces are required to deposit multiple coatings on the fiber tow substrate (one chamber for each material). Each chamber is operated at one temperature suitable to deposit a specific material. As such, depositing multiple coatings of different materials on the fiber tow is time consuming and inefficient.

Therefore, the inventors have provided embodiments of an improved process kit for use in a processing chamber.

### SUMMARY

Multi-zone process kits for use in a deposition chamber are provided herein. In some embodiments, a multi-zone process kit includes a body having a plurality of deposition zones formed in the body; one or more gas injection conduits fluidly coupled to a first side of each of the plurality of deposition zones via a plurality of gas inlets; an exhaust conduit fluidly coupled to a second side of each of the plurality of deposition zones via a plurality of exhaust apertures; and a multi-zone heater having a plurality of heating zones, wherein one or more of the plurality of heating zones corresponds to each of the plurality of deposition zones.

In some embodiments, a deposition chamber includes a chamber body having an interior volume; a plurality of posts coupled to the chamber body and extending into the interior volume; and a multi-zone process kit disposed within the interior volume. The process kit includes: a body having a plurality of deposition zones formed in the body; one or more gas injection conduits fluidly coupled to a first side of each of the plurality of deposition zones via a plurality of gas inlets; an exhaust conduit fluidly coupled to a second side of each of the plurality of deposition zones via a plurality of exhaust apertures; and a multi-zone heater having a plurality of heating zones, wherein one or more of the plurality of heating zones corresponds to each of the plurality of deposition zones, wherein the body of the process kit includes a plurality of features to receive corresponding ones of the plurality of posts.

In some embodiments, a multi-zone process kit includes a body having a plurality of deposition zones formed in the body; one or more gas injection conduits fluidly coupled to a first side of each of the plurality of deposition zones via a plurality of gas inlets; an exhaust conduit fluidly coupled to a second side of each of the plurality of deposition zones via a plurality of exhaust apertures; a multi-zone heater having a plurality of heating zones, wherein one or more of the plurality of heating zones corresponds to each of the plurality of deposition zones; and a plurality of purge zones correspondingly disposed adjacent to the plurality of deposition zones.

Other embodiments and variations of the present disclosure are discussed below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic view of process kit for use in a deposition chamber in accordance with some embodiments of the present disclosure.

FIG. 2 depicts an isometric view of a process kit for use in a deposition chamber in accordance with some embodiments of the present disclosure.

FIG. 3 depicts a schematic cross-sectional of a portion of the process kit of FIG. 2.

FIG. 4 depicts a process kit disposed in a deposition chamber in accordance with some embodiments of the present disclosure.

FIG. 5 depicts a schematic cross-sectional view of a process kit for use in a deposition chamber in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a multi-zone process kit for use in a deposition chamber are provided herein. The disclosed process kit advantageously reduces the time required to deposit composite films on a fiber tow substrate by eliminating the need for separate chambers and providing a plurality of zones within the process kit. The disclosed process kit is also advantageously easily removable for servicing.

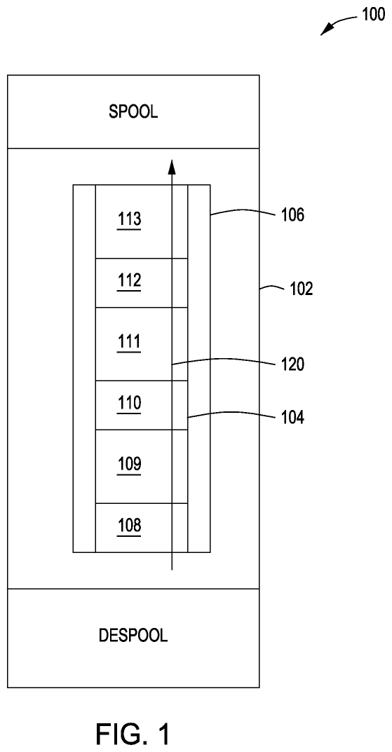

FIG. 1 depicts a schematic view of a deposition chamber 100 having a multi-zone process kit 104 in accordance with some embodiments of the present disclosure. In some embodiments, the deposition chamber 100 may be a continuous chemical vapor deposition (CVD) chamber used to deposit materials on a plurality of fibers of a fiber tow substrate that moves from a despool volume to a spool volume of the deposition chamber 100. The movement of the tow is indicated by arrow 120. As noted above, the inventors have observed that typical processing time to deposit more than one material on the fiber tow substrate is increased because of the utilization of separate chambers, each for depositing a different material. As such, the inventors have developed the process kit 104 having a plurality of volumes, or depositions zones 109, 111, 113, each for depositing a different material. In some embodiments, the process kit 104 may also include purge zones 108, 110, 112 through which purge gas is flowed to clear away any excess material on the fibers. The process kit may be formed of any process-compatible ceramic material such as, for example, silicon carbide coated graphite.

The process kit 104 further includes a multi-zone heater 106 having a plurality of heating zones to heat each deposition zone as desired. In some embodiments, the multi-zone heater 106 may have a plurality of zones corresponding to the plurality of deposition zones 109, 111, 113. In some embodiments, the multi-zone heater 106 may alternatively have two or more heating zones corresponding to each deposition zones.

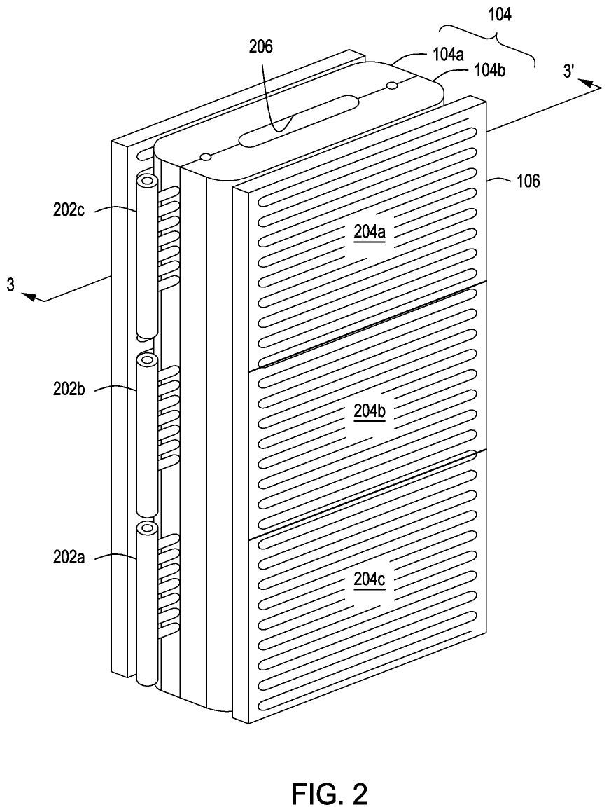

FIG. 2 depicts an isometric view of the process kit 104 as assembled. As shown in FIG. 2, the process kit 104 includes a body having a first portion 104a and a second portion 104b that are coupled to one another to form a passage 206 through which a fiber tow substrate passes. In the embodiment depicted in FIG. 2, the multi-zone heater 106 includes three heating zones 204a, 204b, 204c, which correspond to deposition zones (not shown in FIG. 2) within the process kit 104. The process kit 104 further includes a plurality of gas injection conduits 202a, 202b, 202c to which respective gas sources are coupled for flowing gases into the deposition zones. In some embodiments, the process kit 104 is disposed within a deposition chamber used to deposit boron nitride, silicon-doped boron nitride, silicon nitride, and various carbon containing films on a fiber tow substrate. To facilitate deposition of such materials, the multi-zone heater 106 is disposed in close proximity to the process kit 104 to ensure a desirable heating profile across each deposition zone of the process kit 104.

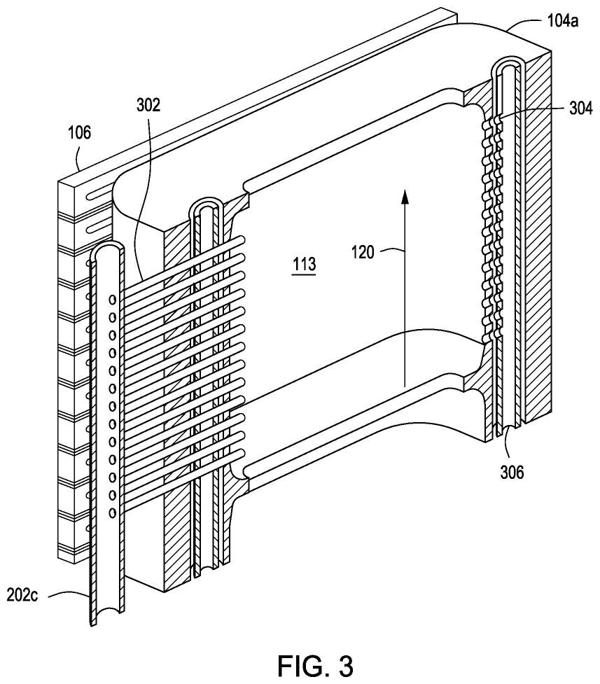

FIG. 3 depicts a schematic cross-sectional view of the process kit 104 taken alone line 3-3′ in FIG. 2. For clarity and brevity, the following description will be made with respect to one deposition zone and applies to each of the plurality of deposition zones 109, 111, 113. As shown in FIG. 3, the gas injection conduit 202c is coupled to a third deposition zone 113 via a plurality of gas inlets 302. In some embodiments, the gas injection conduit 202c may be formed of a quartz and is cooled using a coolant to cool the gas passing through the gas injection conduit 202c and the plurality of gas inlets 302. As a result, parasitic deposition in the gas injection conduit 202c and the plurality of gas inlets 302 is substantially reduced or eliminated. In some embodiments, the gas injection conduit 202c may be cooled by encapsulating the gas injection conduit 202c in a cooled shroud (not shown). In some embodiments, the shroud may be formed of a metal such as, for example, nickel, through which coolant channels extend for flowing a coolant.

Although one gas injection conduit 202c is depicted in FIG. 3 as associated with the third deposition zone 113, the process kit 104 may include two or more gas injection conduits to flow two or more precursors into the third deposition zone 113 for mixing within the deposition zone and depositing onto the fiber tow substrate. By allowing the precursor gases to mix within the deposition zone and not upstream of the deposition zone (i.e., in the gas injection conduit), parasitic deposition within the gas injection conduit(s) and the plurality of gas inlets is further reduced. The plurality of gas inlets 302 may also be grouped into one or more zones to facilitate delivery of separate heterogeneous gas streams or one homogenous gas stream depending on the process parameters.

The process kit 104 includes a plurality of exhaust apertures 304 fluidly coupled to an exhaust conduit 306. In some embodiments, the exhaust conduit 306 may also be formed of quartz and cooled to avoid parasitic deposition in the exhaust conduit 306, which would otherwise result in blockage of the exhaust flow from the deposition zone.

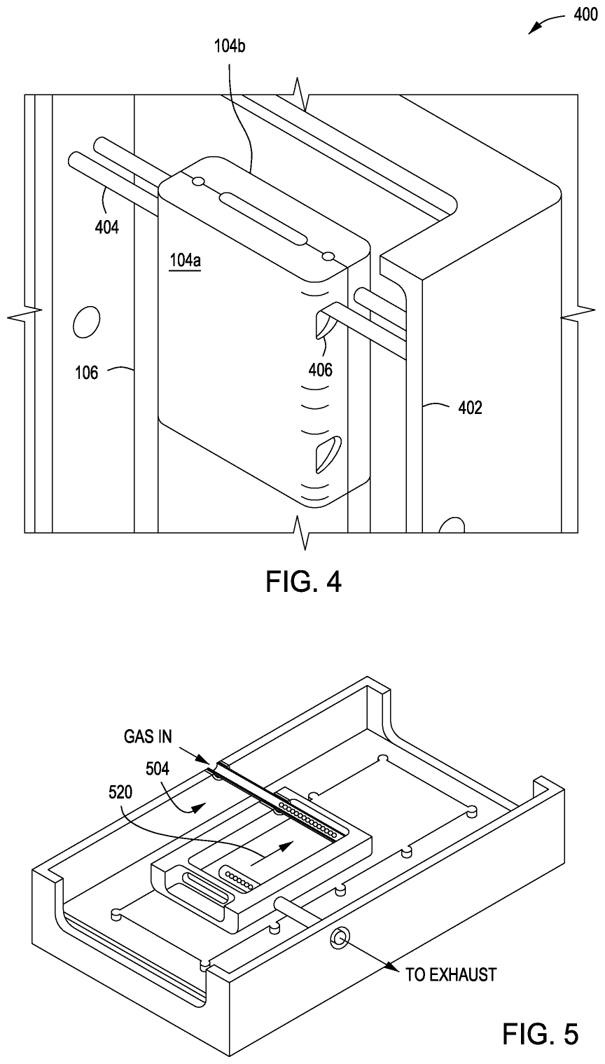

FIG. 4 depicts the process kit 104 disposed within an interior volume of a deposition chamber 400 in accordance with some embodiments of the present disclosure. As shown in FIG. 4, the process kit 104 is coupled to an interior of a chamber body 402 via a plurality of posts 404. The plurality of posts may be fixed to the interior of the deposition chamber 400 using any means (e.g., welding, screws, etc.). To couple the process kit 104 to the chamber body 402, the process kit 104 may include a plurality of features 406 each of which is configured to receive an end of a respective post 404. In some embodiments, the plurality of features are slots through which ends of respective ones of the plurality of posts 404 are inserted to allow the process kit 104 to hang on the plurality of posts 404. The slots are configured to allow thermal expansion of the process kit along an axis parallel to the direction of tow. In some embodiments, the process kit 104 may include one or more holes (not shown) through which pyrometers extend and directly measure the temperature of the tow. Power delivered to the multi-zone heater 106 may be more accurately controlled based on the measurements of the one or more pyrometers.

FIG. 5 depicts a process kit 504 in accordance with some embodiments of the present disclosure. For clarity, only one zone of the process kit 504 is illustrated and described. The process kit 504 is substantially similar to the process kit 104, described above, except that the gas injection conduit 502 and the exhaust conduit 506 are arranged to flow gas parallel to a direction of tow movement illustrated by arrow 520, whereas the process kit 104 is configured to flow gas perpendicular to the direction of tow.

While the foregoing is directed to embodiments of the present disclosure, other and further embodiments of the disclosure may be devised without departing from the basic scope thereof.

1. A multi-zone process kit, comprising:
a body having a plurality of deposition zones formed in the body;
one or more gas injection conduits fluidly coupled to a first side of each of the plurality of deposition zones via a plurality of gas inlets;
an exhaust conduit fluidly coupled to a second side of each of the plurality of deposition zones via a plurality of exhaust apertures; and
a multi-zone heater having a plurality of heating zones, wherein one or more of the plurality of heating zones corresponds to each of the plurality of deposition zones.

2. The multi-zone process kit of claim 1, wherein the body is formed of two portions coupled together.

3. The multi-zone process kit of claim 1, further comprising:
a plurality of purge zones correspondingly disposed adjacent to the plurality of deposition zones.

4. The multi-zone process kit of claim 1, wherein the one or more gas injection conduits and the exhaust conduit are formed of quartz.

5. The multi-zone process kit of any of claims 1 to 4, wherein the one or more gas injection conduits are encapsulated in a cooled shroud.

6. The multi-zone process kit of any of claims 1 to 4, wherein the plurality of gas inlets are divided into one or more zones.

7. The multi-zone process kit of any of claims 1 to 4, wherein the one or more gas injection conduits and the exhaust conduit are configured to flow gas perpendicular to a direction of tow of a fiber tow substrate.

8. The multi-zone process kit of any of claims 1 to 4, wherein the one or more gas injection conduits and the exhaust conduit are configured to flow gas parallel to a direction of tow of a fiber tow substrate.

9. A deposition chamber, comprising:
a chamber body having an interior volume;
a plurality of posts coupled to the chamber body and extending into the interior volume; and
a multi-zone process kit disposed within the interior volume, the multi-zone process kit comprising:
a body having a plurality of deposition zones formed in the body;
one or more gas injection conduits fluidly coupled to a first side of each of the plurality of deposition zones via a plurality of gas inlets;
an exhaust conduit fluidly coupled to a second side of each of the plurality of deposition zones via a plurality of exhaust apertures; and
a multi-zone heater having a plurality of heating zones, wherein one or more of the plurality of heating zones corresponds to each of the plurality of deposition zones,
wherein the body of the process kit includes a plurality of features to receive corresponding ones of the plurality of posts.

10. The deposition chamber of claim 9, wherein the plurality of features are slots configured to allow thermal expansion of the multi-zone process kit in a direction parallel to a direction of tow of a fiber tow substrate.

11. The deposition chamber of claim 9, wherein the multi-zone process kit further comprises:
a plurality of purge zones correspondingly disposed adjacent to the plurality of deposition zones.

12. The deposition chamber of any of claims 9 to 11, wherein the one or more gas injection conduits and the exhaust conduit are formed of quartz.

13. The deposition chamber of any of claims 9 to 11, wherein the plurality of gas inlets are divided into one or more zones.

14. The deposition chamber of claim 13, wherein the one or more gas injection conduits and the exhaust conduit are configured to flow gas perpendicular to a direction of tow of a fiber tow substrate.

15. The deposition chamber of claim 13, wherein the one or more gas injection conduits and the exhaust conduit are configured to flow gas parallel to a direction of tow of a fiber tow substrate.
